(19) United States
(12) Patent Application Publication
(10) Pub. No.: US 2024/0178219 A1
(43) Pub. Date: May 30, 2024

(54) DEVICE WITH PLASMA INDUCED DAMAGE (PID) PROTECTION

(71) Applicant: GlobalFoundries U.S. Inc., Malta, NY (US)

(72) Inventors: Michael J. HAUSER, Albany, NY (US); Micheal J. ZIERAK, Colchester, VT (US)

(21) Appl. No.: 18/072,127

(22) Filed: Nov. 30, 2022

(51) Int. Cl. H01L 27/02; H01L 23/522; H01L 23/528

(52) U.S. Cl. CPC H01L 27/0292; H01L 23/5226; H01L 23/5283; H01L 27/0296

(57) ABSTRACT

The present disclosure relates to semiconductor structures and, more particularly, to a device with plasma induced damage (PID) protection and methods of manufacture and operation. The structure includes: a transistor comprising a gate structure, source region and a drain region, the transistor being on a substrate; and a first gate-protecting line connecting to the gate structure of the transistor and the substrate.

### BACKGROUND

The present disclosure relates to semiconductor structures and, more particularly, to a device with plasma induced damage (PID) protection and methods of manufacture and operation.

Plasma induced damage (PID) is a source of yield loss and product field returns. In particular, PID may occur after a wafer goes through a multi back end of the line (BEOL) tool routing to charge the wafer. In this scenario, PID may cause an early fail and a loss of device performance.

In known circuits, gate protection diodes may help reduce or eliminate PID. However, gate protection diodes add restrictions to a design and reduce performance of a product. In addition, in known circuits, ground rule requirements to ensure an allowed metal to gate oxide area ratios are complex, represent challenges and add limitations to circuit designers.

In known circuits, PID mitigation may include improving tool control, adding gate protection devices to eliminate electrostatic and triboelectric charge accumulation, and limit back end of the line (BEOL) wiring. In an example, a MOSFET may include a reverse diode (or back to back diode) from a gate to a substrate to provide a current leakage path and voltage neutralization if a displacement voltage builds up from the PID. However, in this example, the circuit will only work in an inversion mode because the diode will be forward biased in an accumulation mode. Further, in this example, additional parasitic capacitance and parasitic impedance occurs on a host device (e.g., transistor). Thus, known circuits do not have the ability to prevent parasitic capacitance or parasitic impendence, and include restrictive ground rules.

### SUMMARY

In an aspect of the disclosure, a structure comprises: a transistor comprising a gate structure, source region and a drain region, the transistor being on a substrate; and a first gate-protecting line connecting to the gate structure of the transistor and the substrate.

In an aspect of the disclosure, a structure comprises: a gate structure of a transistor on a substrate; a first gate-protecting line at a first wiring level above the transistor, the first gate-protecting line connecting to the gate structure of the transistor and the substrate and includes a cut which breaks any connection between the gate structure and the substrate; and a second gate-protecting line at a second wiring level above the first wiring level, the second gate-protecting line connecting the gate structure of the transistor and the substrate.

In an aspect of the disclosure, a method comprises: forming a gate structure of a transistor on a substrate; forming a first gate-protecting line at a first wiring level above the transistor, the first gate-protecting line connecting to the gate structure of the transistor and the substrate and includes a cut which breaks any connection between the gate structure and the substrate; and forming a second gate-protecting line at a second wiring level above the first wiring level, the second gate-protecting line connecting the gate structure of the transistor and the substrate, wherein the cut is formed after the formation of the second gate-protecting line.

### BRIEF DESCRIPTION OF THE DRAWINGS

The present disclosure is described in the detailed description which follows, in reference to the noted plurality of drawings by way of non-limiting examples of exemplary embodiments of the present disclosure.

FIG. 1 shows a transistor circuit with gate-protecting metal lines, in accordance with aspects of the present disclosure.

FIG. 2 shows a transistor circuit with gate-protecting metal lines, in accordance with additional aspects of the present disclosure.

FIG. 3 shows a transistor circuit with gate-protecting metal lines, in accordance with additional aspects of the present disclosure.

FIG. 4 shows a top down layout view of the transistor circuit with gate-protecting metal lines, amongst other features, in accordance with additional aspects of the present disclosure.

FIG. 5 shows a cross-sectional layout view of transistor circuit with gate-protecting metal lines, amongst other features, in accordance with aspects of the present disclosure.

### DETAILED DESCRIPTION

The present disclosure relates to semiconductor structures and, more particularly, to a device with plasma induced damage (PID) protection and methods of manufacture and operation. In embodiments, the present disclosure includes a protecting metal line from a gate pad to a local n-well or a substrate. The present disclosure may also include lower metal lines that have a sever or are broken between a gate to a n-well or a substrate. Advantageously, the present disclosure may provide a method of PID protection while eliminating issues in known circuits such as restrictive ground rules, parasitic impedance, parasitic capacitance, and an inability to operate devices in an accumulation mode. In addition, the present disclosure may also provide the ability to protect metal-oxide-semiconductor field-effect transistors (MOSFETS) with minimal additional area.

In more specific embodiments, the present disclosure may include a metal line connecting a MOSFET gate contact to an n-well or a substrate to create a conductive path for charge equilibrium during BEOL processing to maintain approximately a constant net zero volts across an oxide. In embodiments, fabricating such structure may include fabricating a lower metal line (i.e., lowest wiring level above a transistor) from either the gate to the substrate or the gate to the n-well. After the formation of the lower metal line is completed, an upper metal line may be fabricated over the lower metal line. In this configuration, the lower metal line may be severed after fabricating the upper metal line. The method may further include additional metal lines at upper levels, with the lower metal lines being broken.

The device of the present disclosure may be manufactured in several ways using a number of different tools. In general, though, the methodologies and tools are used to form structures with dimensions in the micrometer and nanometer scale. The methodologies, i.e., technologies, employed to manufacture the device of the present disclosure have been adopted from integrated circuit (IC) technology. For example, the structures are built on wafers and are realized in films of material patterned by photolithographic processes on the top of a wafer. In particular, the fabrication of the device uses three basic building blocks: (i) deposition of thin films of material on a substrate, (ii) applying a patterned mask on top of the films by photolithographic imaging, and (iii) etching the films selectively to the mask.

FIG. 1 shows a transistor circuit with gate-protecting metal lines, in accordance with aspects of the present disclosure. In FIG. 1, the transistor circuit 10 includes a transistor 11 (which may be fabricated over a local N-well (NW)) and a gate-protecting metal line 14 on a first wiring level (e.g., M1 wiring level). In embodiments, the gate-protecting metal line 14 is at a lowest wiring level (i.e., M1 wiring level) of a back end of the line (BEOL) stack.

In FIG. 1, the transistor 11 comprises a gate (G), drain (D), and a source (S). In embodiments, the transistor 11 may be a NMOS transistor; however, embodiments are not limited to only a NMOS transistor. For example, the transistor 11 may be a PMOS transistor. In FIG. 1, the gate-protecting metal line 14 may connect the gate (G) of the transistor 11 to the semiconductor substrate or an N-well (NW).

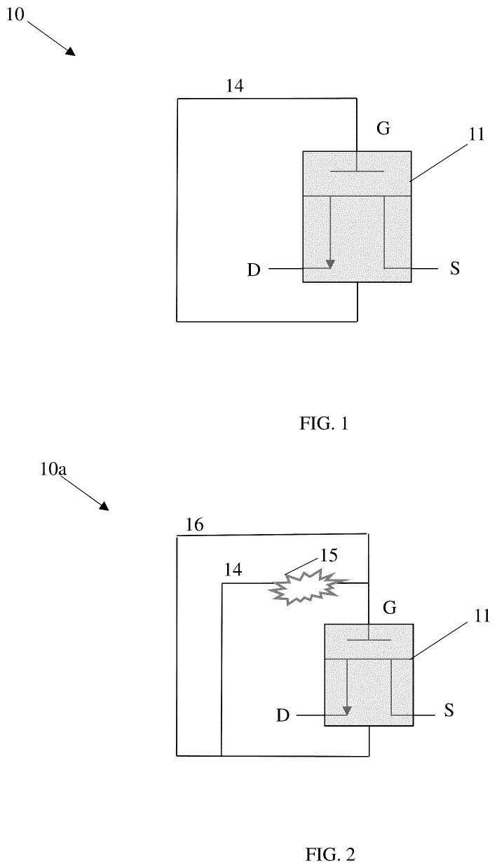

In FIG. 2, the transistor circuit 10a includes a gate-protecting metal line 16 on an upper wiring line, e.g., M2 wiring level. In embodiments, the gate-protecting metal line 16 is at a higher wiring level (i.e., M2 wiring level above the M1 wiring level) of the back end of the line (BEOL) stack. The gate-protecting metal line 16 may connect the gate (G) of the transistor 11 to the semiconductor substrate or local N-well (NW). The gate-protecting metal line 16 may be a duplicative connection between the gate (G) of the transistor 11 to the semiconductor substrate or local N-well (NW). Due to this duplication, the gate-protecting metal line 14 may be broken or severed (e.g., etched) as represented by reference numeral 15, which breaks the connection between the gate (G) of the transistor 11 and the semiconductor substrate or local N-well (NW). The gate-protecting metal line 14 may be severed or cut after formation of the gate-protecting metal line 16. The gate-protecting metal line 16 maintains the direct connection between the gate and n-well or substrate.

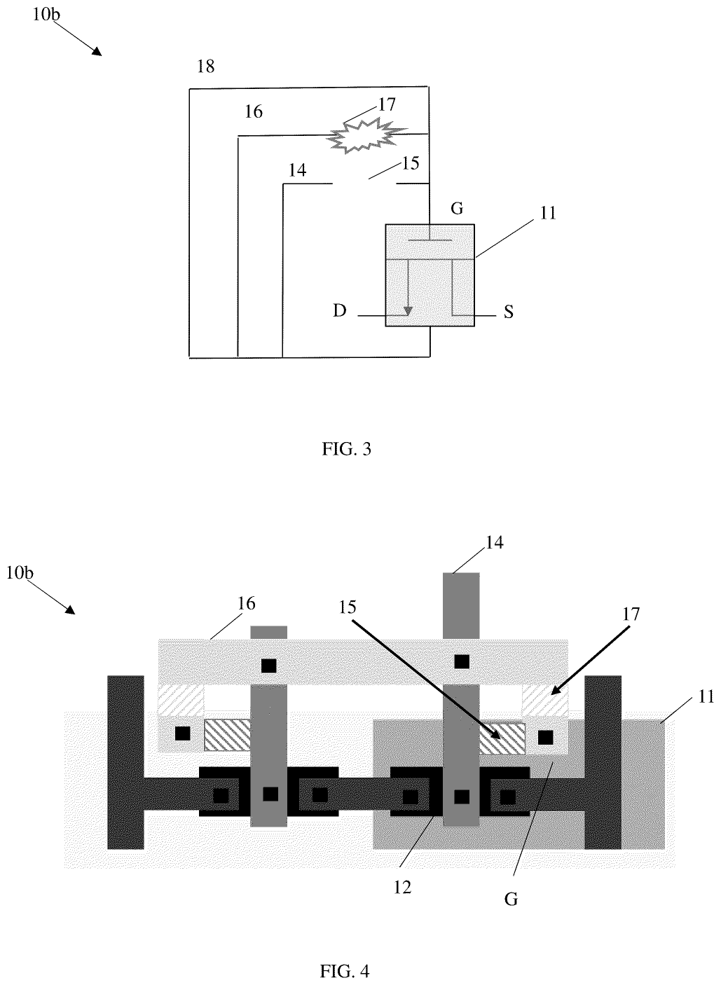

In FIG. 3, the transistor circuit 10b includes a gate-protecting metal line 18 on another wiring level, e.g., M3 wiring level. In embodiments, the gate-protecting metal line 18 is at a higher wiring level than the metal lines 14, 16 (i.e., M3 wiring level above the M1, M2 wiring levels) of the back end of the line (BEOL) stack. The gate-protecting metal line 18 may connect the gate (G) of the transistor 11 to the semiconductor substrate or local N-well (NW).

The M3 gate-protecting metal line 18 may be a duplicative connection between the gate (G) of the transistor 11 to the semiconductor substrate or local N-well (NW). In this circuit design, though, the gate-protecting metal lines 14, 16 may be severed or cut as represented by reference numerals 15, 17, respectively. The gate-protecting metal line 16 may be severed or cut after formation of the gate-protecting metal line 18. The gate-protecting metal line 18 maintains the direct connection between the gate and n-well or substrate.

Although the circuits 10, 10a, 10b are shown with respective gate-protecting metal lines 14, 16, and 18 corresponding to M1, M2, and M3 wiring levels, it should be understood by those of skill in the art that other gate-protecting metal lines at different wiring levels are also contemplated herein. For example, there may be any number “N” gate-protecting metal lines in the BEOL stack, with “N” being any integer corresponding to a number of wiring levels below the non-metal lines of the transistor circuit 10. Further, in embodiments, each of the gate-protecting metal lines 14, 16, and 18 may comprise aluminum, copper, tungsten, or any other suitable metal. Advantageously, by breaking (e.g., etching) the gate-protecting metal lines 14, 16 in FIGS. 2 and 3, plasma induced damage (PID) protection may be realized in a circuit without restrictive ground rules, parasitic impedance, parasitic capacitance, an inability to operate devices in accumulation, and a large area impact.

FIG. 4 shows a top down layout view of the transistor circuit with gate-protecting metal lines of FIG. 3, amongst other features, in accordance with aspects of the present disclosure. In the top down layout 10b, gate-protecting metal line 16 and gate-protecting line 14 are shown at different wiring levels. Gate-protecting metal line 18 of FIG. 3 is not shown. In the fabrication processes, the gate-protecting metal line 14 may have a sever or cut as represented as reference numeral 15 by a conventional etching process. The etching process for the gate-protecting metal line 14 will occur after the completion of gate-protecting metal line 16. Thereafter, the gate-protecting metal line 16 may have a cut as represented as reference numeral 17 by a conventional etching process. The etching process for the gate-protecting metal line 16 will occur after the completion of gate-protecting line 18. In this way, the gate-protecting metal lines 14, 16 have a cut at references numerals 15, 17 to provide plasma induced damage (PID) protection. In FIG. 4, the gate-protecting lines 14 and 16 are connected to a semiconductor substrate or local N-well (NW) 12. Also, in FIG. 4, the steps of fabricating of upper wiring lines and etching of the lower wiring lines may be repeated for any number of wiring levels in the BEOL stack (i.e., all wiring levels below the non-metal lines of the transistor circuit).

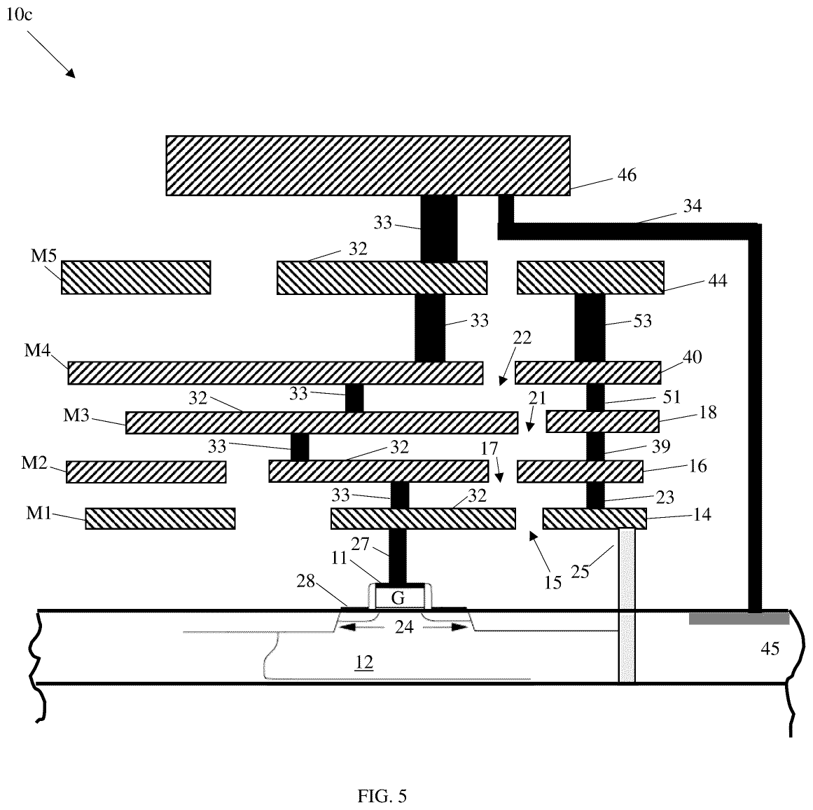

FIG. 5 shows a cross-sectional layout view of transistor circuit with gate-protecting metal lines, amongst other features. In FIG. 5, the transistor circuit 10c includes the transistor 11 formed on a semiconductor substrate or local N-well (NW) 12 and an active region 24 (i.e., Rx region). A silicide 28 may be formed on the gate (G), drain (D), and source (S) of the transistor 11. Contacts 25, 27 may be formed to the gate and the source and drain regions. In further embodiments, the gate-protecting metal line 14 may be severed at location 15 to break a connection between the gate-protecting metal line 14 and one of the silicide 28 and the semiconductor substrate or local N-well (NW) 12. Conventional wiring line 32 and vias 33 may be formed in back end of line wiring levels M1-M5, connecting to the transistors 11.

The gate-protecting metal lines 14, 16, 18, 40, 44 may be formed on respective wiring levels M1-M5. The gate-protecting metal lines 14, 16, 18, 40 may be formed at lower wiring levels M1-M4, than the top gate-protecting metal line 44 on wiring level M5. The gate-protecting metal lines 14, 16, 18, 40 may each include a sever or cut at reference numerals 15, 17, 21, 22, respectively, to ensure that there is no connection between the gate structure (G) and the substrate or N-well 12. Via 53 may be connected between the gate-protecting metal line 40 and the top gate-protecting metal line 44. Via 51 may be connected between the gate-protecting metal line 40 and the gate-protecting metal line 18. Via 39 may be connected between the gate-protecting metal line 18 and the gate-protecting metal line 16. Via 23 may be connected between the gate-protecting metal line 16 and the gate-protecting metal line 14. A tie down device (e.g., a stack of diodes) as represented by reference numeral 45 may be used, for example, in bulk Si technology. As shown in FIG. 5, the tie down device 45 may be provided in the semiconductor substrate and, particularly, within the local N-well (NW) 12. The tie down device 45 may also be connected to the top metal line 46 (e.g., a pad 46), above the gate-protecting metal lines 14, 16, 18, 40, through wiring lines represented at reference numeral 34. The wiring lines 34 may be representative of back end of the line structures such as via interconnects and wiring structures as is known in the art. In embodiments, the tie down device 45 may provide electrostatic discharge protection (ESD) as is known in the art.

In FIG. 5, the active region 24 (i.e., Rx region 24) may comprise a semiconductor substrate within a local N-well (NW) 12. In embodiments, an ion implantation process with an n-type dopant (e.g., arsenic) may be used to form the N-well 12. The gate structure of the transistor 11 may be formed on the active region 24 by conventional deposition methods, e.g., CVD, followed by conventional lithography, etching, and patterning processes. The source and drain regions may be formed by a conventional ion implantation process or epitaxial growth process as is known in the art such that no further explanation is required for a completed understanding of the present disclosure. The vias and metal lines may be deposited by a CVD process, and may be patterned using conventional lithography and etching as is known in the art such that no further explanation is needed to understand the disclosure.

The silicide 28 may be formed on the patterned semiconductor materials. As should be understood by those of skill in the art, the silicide process begins with deposition of a thin transition metal layer, e.g., nickel, cobalt, or titanium, over fully formed and patterned semiconductor devices (e.g., source and drain regions and gate structure). After deposition of the material, the structure is heated allowing the transition metal to react with exposed silicon (or other semiconductor material as described herein) in the active region 24 of the semiconductor device (e.g., source, drain, gate contact region) forming a low-resistance transition metal silicide 28. Following the reaction, any remaining transition metal is removed by chemical etching, leaving silicide contacts 28 in the active regions of the device.

In embodiments of the present disclosure, the top gate protecting metal line 44 at wiring level M5 may be cut (as shown in FIG. 5). Further, in other embodiments, the transistor circuit 10c in FIG. 5 may not include the tie down device 45 (e.g., a stack of diodes).

The devices may be utilized in system on chip (SoC) technology. The SoC is an integrated circuit (also known as a “chip”) that integrates all components of an electronic system on a single chip or substrate. As the components are integrated on a single substrate, SoCs consume much less power and take up much less area than multi-chip designs with equivalent functionality. Because of this, SoCs are becoming the dominant force in the mobile computing (such as in Smartphones) and edge computing markets. SoC is also used in embedded systems and the Internet of Things.

The method(s) as described above is used in the fabrication of integrated circuit chips. The resulting integrated circuit chips may be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either surface interconnections and buried interconnections or both surface interconnections and buried interconnections). In any case the chip is then integrated with other chips, discrete circuit elements, and/or other signal processing devices as part of either (a) an intermediate product, such as a motherboard, or (b) an end product. The end product may be any product that includes integrated circuit chips, ranging from toys and other low-end applications to advanced computer products having a display, a keyboard or other input device, and a central processor.

The descriptions of the various embodiments of the present disclosure have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed:

1. A structure comprising:
a transistor comprising a gate structure, a source region and a drain region, the transistor on a substrate; and
a first gate-protecting line connecting to the gate structure of the transistor and the substrate.

2. The structure of claim 1, wherein the first gate-protecting line comprises a metal wiring structure on a first wiring level.

3. The structure of claim 1, wherein the substrate comprises an N-well and the first gate-protecting line connects to the N-well and the gate structure.

4. The structure of claim 1, further comprising a second gate-protecting line connecting to the gate structure of the transistor and the substrate.

5. The structure of claim 4, wherein the second gate-protecting line comprises a metal wiring structure on a wiring level above the first wiring level.

6. The structure of claim 5, wherein the first gate-protecting line includes a cut which breaks a connection between the gate structure and the substrate.

7. The structure of claim 4, further comprising a third gate-protecting line which connects the gate structure of the transistor to the substrate.

8. The structure of claim 7, wherein the first gate-protecting line and the second gate-protecting line each include a cut which breaks a connection between the gate structure and the substrate.

9. The structure of claim 8, wherein the third gate-protecting line comprises a metal wiring structure on a wiring level above the first gate-protecting line and the second gate-protecting line.

10. The structure of claim 1, further comprising a tie down device connected to a wiring level above the first gate-protecting line.

11. The structure of claim 10, wherein the tie down device provides electrostatic discharge protection (ESD) to at least the first gate-protecting line.

12. A structure comprising:
a gate structure of a transistor on a substrate;
a first gate-protecting line at a first wiring level above the transistor, the first gate-protecting line connecting to the gate structure of the transistor and the substrate and includes a cut which breaks any connection between the gate structure and the substrate; and
a second gate-protecting line at a second wiring level above the first wiring level, the second gate-protecting line connecting the gate structure of the transistor and the substrate.

13. The structure of claim 12, further comprising a tie down device connected to a third wiring level above the first wiring level and the second wiring level.

14. The structure of claim 13, wherein the tie down device provides electrostatic discharge protection (ESD) to the first gate-protecting line and the second gate-protecting line.

15. The structure of claim 12, wherein the first gate-protecting line connects the gate structure of the transistor to the substrate.

16. The structure of claim 12, wherein the second gate-protecting line connects the gate structure of the transistor to the substrate.

17. The structure of claim 12, further comprising a third gate-protecting line which connects the gate structure of the transistor to the substrate and the second gate-protecting line includes a break between the gate structure and the substrate.

18. The structure of claim 12, wherein the substrate comprises an N-well.

19. The structure of claim 12, wherein the first gate-protecting line and the second gate-protecting line are at back end of the line wiring levels.

20. A method comprising:
forming a gate structure of a transistor on a substrate;
forming a first gate-protecting line at a first wiring level above the transistor, the first gate-protecting line connecting to the gate structure of the transistor and the substrate and includes a cut which breaks any connection between the gate structure and the substrate; and
forming a second gate-protecting line at a second wiring level above the first wiring level, the second gate-protecting line connecting the gate structure of the transistor and the substrate,
wherein the cut is formed after the formation of the second gate-protecting line.
